(19) United States
(12) Patent Application Publication
(10) Pub. No.: US 2005/0284375 A1
(43) Pub. Date: Dec. 29, 2005

(54) Method and apparatus for processing a workpiece

(76) Inventors: Kodjo Leeds, Kalispell, MT (US); Ryan Pfeifle, Kalispell, MT (US)

Correspondence Address: PERKINS COIE LLP/SEMITOOL, PO BOX 1208, SEATTLE, WA, 98111-1208, US

(21) Appl. No.: 10/877,779

(22) Filed: Jun. 24, 2004

(51) Int. Cl. C23C 16/00

(52) U.S. Cl. 118/730

(57) ABSTRACT

An apparatus for processing a workpiece, such as a semiconductor wafer, includes a rotor for holding workpieces within a process chamber. A gas pressure seal around the shaft of the rotor has a shaft adapter on the shaft and an o-ring providing a seal between the shaft and the shaft adapter. A front o-ring seals the shaft adapter directly to the back surface of the rotor. A motor ring around the shaft adapter is spaced apart from the shaft adapter to form an annular gas flow path between them. A retainer ring attached to the motor ring is sealed against the motor ring by a motor ring o-ring. An inert gas source is connected to a gas inlet on the motor ring and provides a flow of gas through the seal during workpiece processing. This prevents process gases in the chamber from leaking out and also prevents contaminants from leaking into the chamber. The flow of inert gas can be reduced temporarily to avoid dilution of the process gas in the chamber.

### BACKGROUND OF THE INVENTION

The invention relates to surface preparation, cleaning, rinsing and drying of semiconductor wafers and similar workpieces. In the processing of wafers, it is often necessary to apply a fluid onto the wafer in either liquid, vapor or gaseous form. Such fluids are used to, for example, etch the wafer surface, clean the wafer surface, dry the wafer surface, passivate the wafer surface, deposit films on the wafer surface, etc. The wafers are often loaded into a rotor within a process chamber, for processing. By spinning the wafers in the rotor, fluids can more evenly be applied to the wafers. Spinning can also help in drying the wafers, with the centrifugal forces generated by spinning flinging liquid off of the wafers.

More recently, processing with ozone has been used instead of using acids and caustics. While ozone is toxic and corrosive, it is much more easily handled in comparison to the conventional acids and caustics. In addition, it can be easily converted to oxygen, so that it can be disposed of with less environmental affect. In use, ozone is introduced into a process chamber as a dry gas, or mixed with a liquid or another gas or steam, or both. For some processing steps, having a high ozone concentration in the chamber is advantageous. The ozone is advantageously confined or sealed within the process chamber. However, since the rotor shaft which supports the rotor passes out of the chamber, sealing the chamber presents special engineering challenges.

### SUMMARY OF THE INVENTION

A new workpiece processing system having an improved gas pressure seal has now been invented. The system offers better performance and reliability, resulting from the new gas pressure seal design. In new workpiece processing methods, the flow of gas through the gas pressure seal is controlled to avoid diluting process gases in the process chamber. Accordingly, processing of workpieces can be achieved more quickly and more consistently.

In one aspect, the new system includes a rotor for holding workpieces. within the process chamber. A shaft supports the rotor for rotation within the process chamber. The new gas pressure seal around the shaft includes a shaft adapter, with a shaft o-ring or other seal element providing a seal between the shaft and the shaft adapter. A separate front o-ring or other seal element provides a seal between the shaft adapter and the rotor. A motor ring around the shaft adapter is spaced apart from the shaft adapter to form an annular gas flow path between them. The seal elements improve the sealing effectiveness of the new gas pressure seal.

In another aspect, a retainer ring is attached to the motor ring and sealed against the motor ring by a motor ring o-ring or seal element. A seal ring is optionally attached to the retainer ring, with the seal ring projecting into a groove on the back surface of the rotor. A gas inlet and a gas outlet in the motor ring provide a gas flow passageway through the motor ring to ring grooves on an outer surface of the shaft adapter.

In another aspect, threads or ridges are provided on the shaft adapter, with the motor ring surrounding the ridges to create a labyrinth flow path through the seal.

Other features and advantages of the invention will be apparent to persons knowledgeable in this technology, from the following description taken together with the accompanying drawings. While the drawings show a single embodiment of the invention, various changes, modifications and substitutions can of course be made within the scope of the invention. The invention resides as well in sub-combinations of the features described and in the individual components.

### BRIEF DESCRIPTION OF THE DRAWINGS

In the drawings, wherein the same reference number denotes the same element throughout the several views:

FIG. 1 is a front perspective view of a workpiece processing system with various covers removed for purpose of illustration.

FIG. 2 is rear perspective view of the processing system of FIG. 1.

FIG. 3 is a perspective view of a processing chamber assembly shown in FIG. 2.

FIG. 4 is a perspective view of the rotor in the processing chamber assembly shown in FIGS. 2 and 3.

FIG. 5 is a section view of the processing chamber assembly and rotor shown in FIGS. 2 and 3.

FIG. 6 is an exploded perspective view of a novel gas pressure seal as used in the system shown in FIGS. 1 and 2.

FIG. 7 is a section view of the installed seal shown in FIG. 6.

FIG. 8 is a section view of the motor shaft adapter of the seal shown in FIGS. 6 and 7.

FIG. 9 is a section view of the retainer ring of the seal shown in FIGS. 6 and 7.

FIG. 10 is an enlarged detail view of the retainer ring shown in FIG. 9

FIG. 11 is a front-end view of the motor adapter ring of the seal shown in FIGS. 6 and 7.

FIG. 12 is a section view taken along line 12-12 of FIG. 11.

FIG. 13 is a section view taken along line 13-13 of FIG. 11.

FIG. 14 is a section view taken along line 14-14 of FIG. 11.

FIG. 15 is a perspective view of an automated system for use in ozone and other types of processing.

### DETAILED DESCRIPTION OF THE DRAWINGS

The terms workpiece, wafer, or semiconductor wafer, as used here, mean any flat media, including semiconductor wafers and other substrates or wafers, glass, mask, and memory media, MEMS substrates, flat panel displays, rigid disk or optical media, thin film heads, or any other substrate on which micro-electronic, micro-mechanical, or micro electro-mechanical devices may be formed. These and similar articles are collectively referred to here as a “wafer” or “workpiece”.

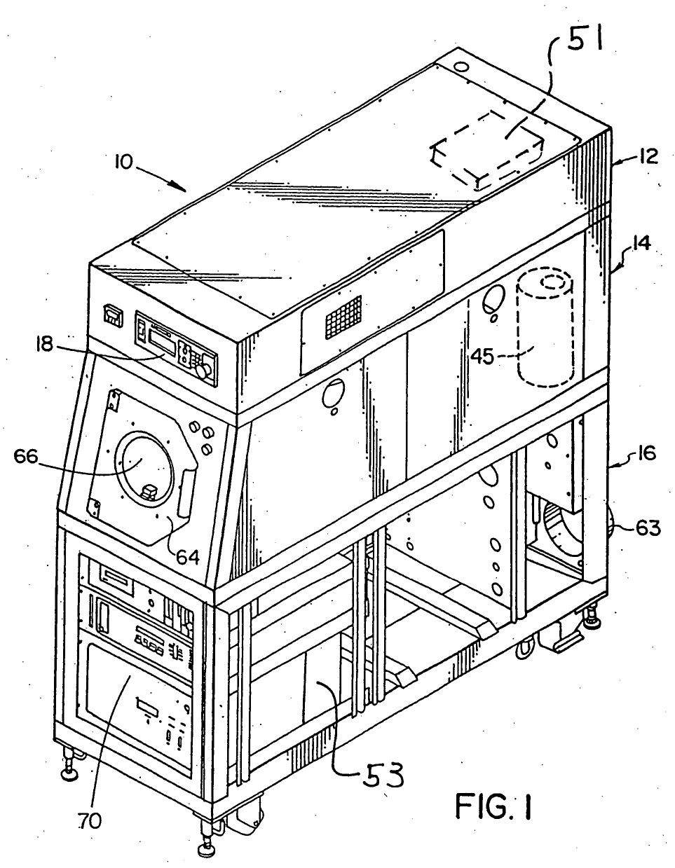

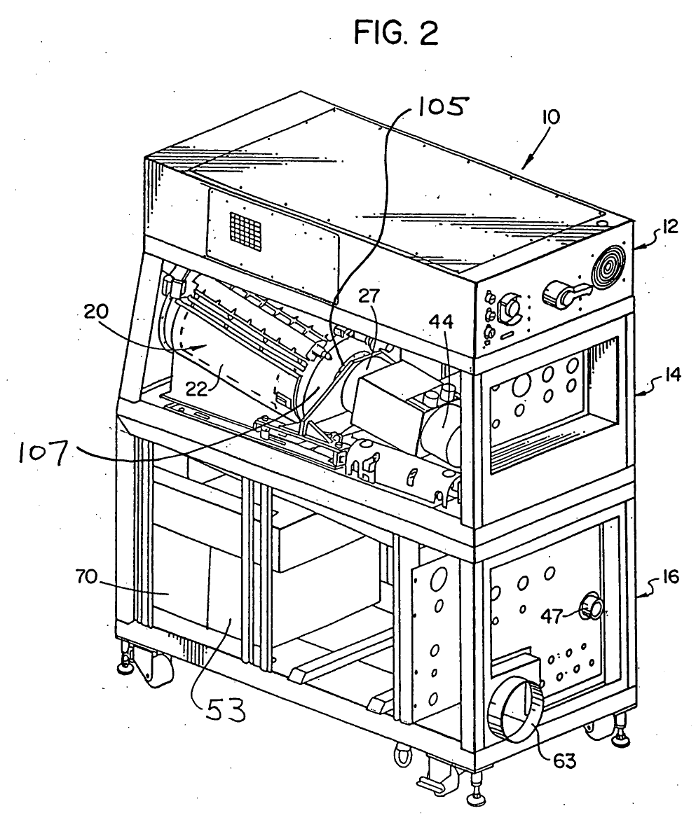

Turning now in detail to the drawings, as shown in FIGS. 1 and 2, a workpiece processing system 10 may be used to process workpieces of various sizes, but is typically configured to process workpieces of one size, such as 200 or 300 mm diameter semiconductor wafers. A first or top section 12 of the system 10 preferably includes a system controller 18, which includes a control panel and display at the front of the first section 12 for controlling and monitoring operation of the system. The first section 12 also preferably includes a system power supply and any other electrical or electronic devices required for performing the various system operations.

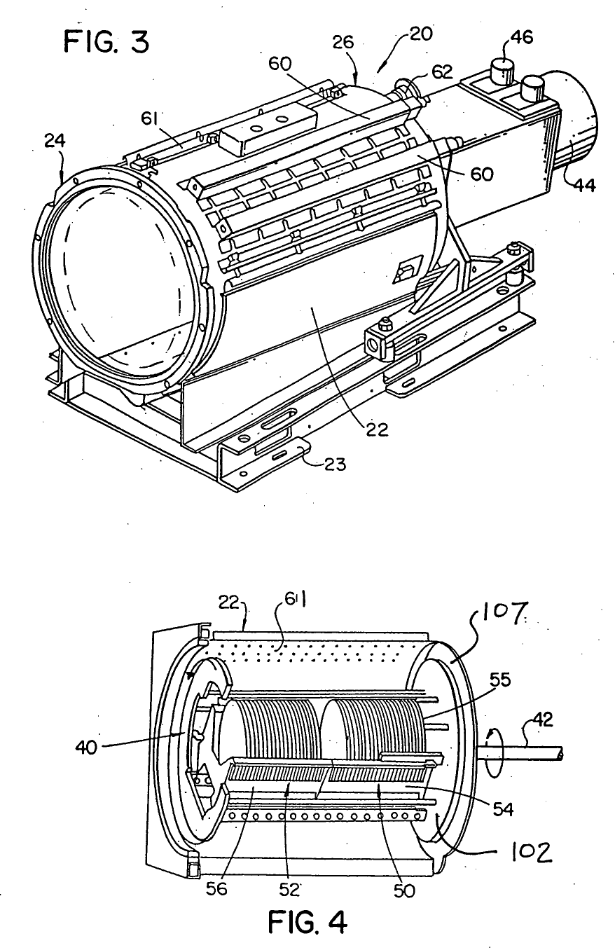

A second or middle section 14 includes a processing chamber assembly 20, as illustrated in FIGS. 2 and 3. The processing chamber assembly 20 includes a substantially cylindrical processing chamber 22 or bowl that is mounted on support mounts 23. The support mounts 23 are preferably bolted to support beams or another suitable base structure in the second section 14.

The second section 14 further includes a door 64, shown in FIG. 1, to provide access into the processing chamber 22. The door 64 preferably forms a seal with a front end 24 of the processing chamber 22, when the door is closed and locked. A window 66 is preferably located in the door 64 for allowing visual inspection into the processing chamber 22.

The processing chamber 22 may be oriented horizontally but is preferably inclined upwardly at an angle of, for example, 5-30°, and preferably about 10°, so that the front end 24 of the processing chamber 22 is at a higher elevation than the back end 26 of the processing chamber 22. Examples of such a processing chamber 22 and chamber assembly 20 are described in U.S. Pat. No. 6,418,945, incorporated by reference.

A rotor 40, as illustrated in FIG. 4, is preferably rotatably supported within the processing chamber 22. A drive shaft 42 extends from the back of the rotor 40 into a motor 44 located at the back end 26 of the processing chamber 22. Power cables extending from the system controller 18 in the first section 12 preferably provide electrical power and control to the motor 44 via connectors 46. The rotor 40 may be designed to hold carriers or cassettes containing workpieces, as described in U.S. Pat. No. 6,418,945 or U.S. Pat. No. 6,723,174, incorporated herein by reference. Alternatively, the rotor may be designed to hold the workpieces directly, such as in U.S. Pat. No. 5,784,797, incorporated herein by reference.

Depending upon the chemicals to be used in the processing system 10, the rotor 40 and the processing chamber 22, as well as other components exposed to the chemicals, may be made of stainless steel, or alternatively the rotor and processing chamber material may be Teflon® (i.e., fluorine containing resins), or another suitable material. In a preferred embodiment, harsh chemicals, such as acids and solvents (e.g., HF, HCl, H₂SO₄, and H₂O₂), are not used in the processing system 10, so that a stainless steel processing chamber 22 and rotor 40 may be used, and so that any negative impact on the environment is substantially minimized.

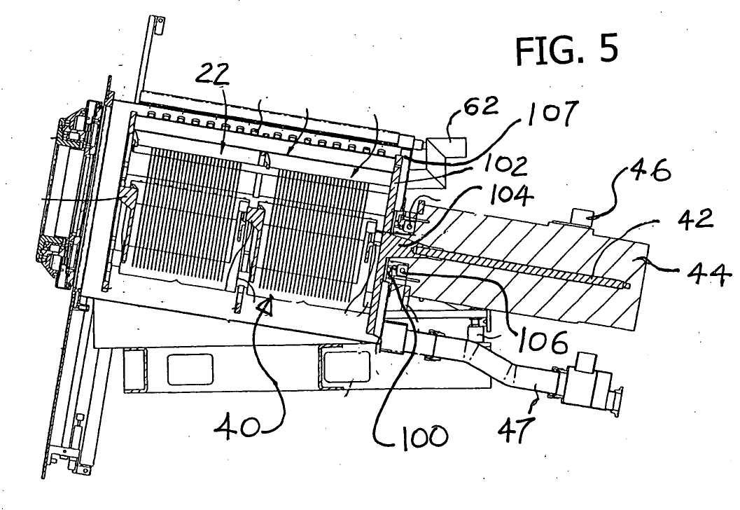

As illustrated in FIGS. 3 and 4, spray manifolds 60 for delivering processing fluid and/or rinse water preferably extend substantially along the entire length of the processing chamber 22. The manifolds 60 have spray nozzles 61 or other openings directed into the processing chamber 22 for spraying liquids or gases into the processing chamber 22. The spray system in the chamber 22 is preferably designed as described in U.S. patent application Ser. No. 10/199,998, filed Jul. 19, 2002, and incorporated herein by reference. As shown in FIG. 5, a vent 62 is preferably included to exhaust gases or vapors from the processing chamber 22, as well as a drain 47 to remove liquids from the processing chamber 22.

The processing chamber 22 may further include various other components to enhance processing of the workpieces 55. For example, as shown in FIG. 1, the processing chamber 22 may include: (a) an anti-static generator 51 to reduce static electricity within the chamber 22; (b) one or more heaters 53 to heat the workpieces 55 and/or the processing and or rinsing fluids; (c) an ozone destructor 45 to convert ozone into oxygen.

The third section 16 preferably serves as a process fluid storage compartment. For uses involving ozone gas, an ozone generator 70 is connected with the processing chamber 22 for providing ozone gas into the processing chamber 22. In general the ozone generator 70 is connected to a gas spray manifold 61 in the processing chamber 22 via one or more ozone delivery lines (not shown). Since some processing steps use large amounts of ozone, the ozone generator 70 is advantageously a high capacity ozone generator that can generate at least 90 g/hour of ozone. If needed, separate cooling water lines may be routed to the ozone generator.

A de-ionized (DI) water supply supplies water to spray nozzles 61 in the processing chamber 22. The DI water may be supplied from a DI water reservoir located within the system 10, or may be supplied from an external source via one or more fluid delivery lines. One or more heaters 53, if used, heat the DI water before it enters the processing chamber 22.

The lower section 16 may contain additional processing fluid supplies, such as an ammonium hydroxide (NH₄OH) supply, a purge gas and/or drying gas source (e.g., N₂ gas generator), a compressed dry air (CDA) source, and/or any other suitable processing fluid supplies. These fluid supplies, if used, connect with nozzles, ports, or other application in the processing chamber 22, via one or more fluid delivery lines. The system 10 typically will include pumps, filters, and/or other components for effectively providing the processing fluids and/or gases into the processing chamber 22. Alarms, sensors, and other monitoring devices to detect processing fluid levels in the processing chamber, may also be included. While the system 10 is described here as having the three sections, and with each of the sections containing specified components, separate sections are not needed. The various components also need not be located in any particular section or module. In addition, the system 10 may also be designed as a single module or section, or with 2, 3 or more modules or sections.

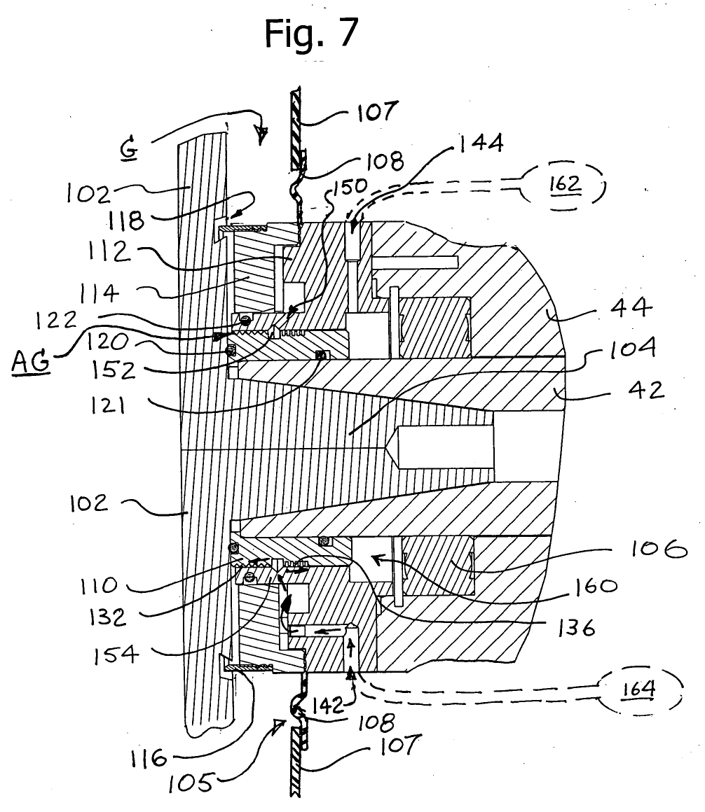

Referring now to FIGS. 5 and 7, the rotor 40 has a back plate 102 having a collar 104 which extends out through an opening 105 (shown in FIG. 2) in the back wall 107 of the processing chamber 22. The rotor shaft 42 is attached to the back plate 102 and is engaged by the motor 44. A bearing 106 rototably supports the shaft 42 and the rotor 40. A seal 100 around the rotor shaft 42 prevents fluids in the chamber from leaking out through the opening 105. Leaking of some fluids, such as ozone gas, could rapidly cause corrosion of the motor 44 and other components, resulting in failure of the system 10. Accordingly, the design of the seal 100 is an important factor in the performance of the system. Since the seal must allow the rotor shaft 42 to turn, traditional fixed or static seals cannot be used. Moreover, the seal must avoid creating contaminant particles which could damage the workpieces.

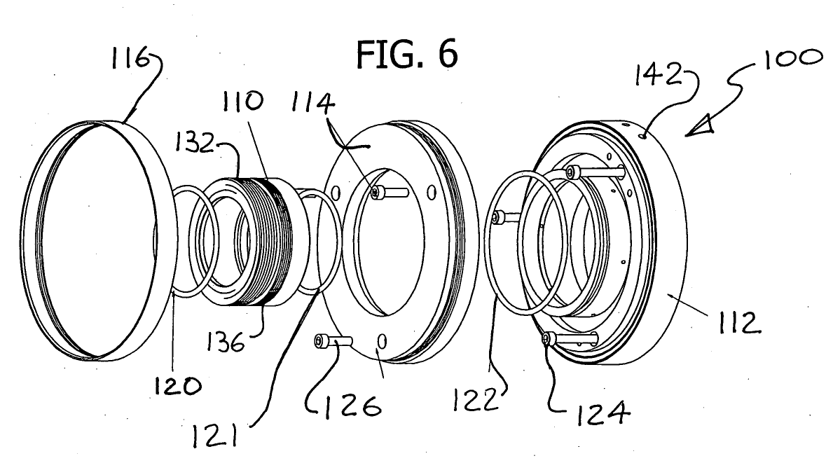

Turning now to FIG. 7, the seal 100 includes a shaft adapter 110 around the collar 104 or shaft 42. A motor ring 112 surrounds the shaft adapter 110. A retainer ring 114 also surrounds the shaft adapter 110, between the back plate 102 and the motor ring 112. A seal ring 116 is attached around the front end of the retainer ring 114 and projects outwardly or forwardly into a groove 118 in the backside of the back plate 102. A shaft adapter o-ring 120 seals the front surface of the shaft adapter 110 against the back surface of the back plate 102. A motor ring o-ring 122 seals the motor ring with the retainer ring 114. The shaft adapter 110 is attached to and spins with the shaft 42. The other components of the seal 100 are attached and supported, directly or indirectly, to the motor 44, and are consequently fixed in place. As shown in FIG. 6, the motor ring 112 is attached to the motor 44 via bolts 124. The retainer ring 114 is attached to the motor ring 112 via bolts 126. The seal ring 116, which is preferably Teflon, provides a supplemental mechanical barrier to the flow of any liquid into the seal 100. The other seal components are preferably metal, e.g., stainless steel.

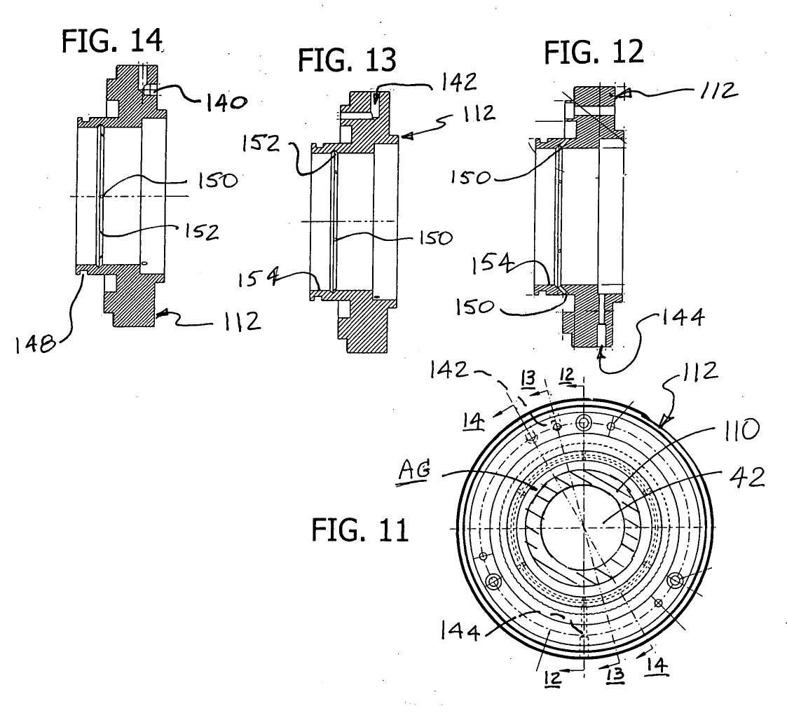

The shaft adapter 110 is spaced apart slightly from the motor ring 112 by an annular gap AG (shown magnified in FIG. 11). The radial clearance between, or difference in the diameters of, the shaft adapter 110 and the motor ring 112 preferably ranges from about 0.005-0.025; 0.007 or 0.008 to 0.015; or 0.012 or 0.009 to 0.011 inches. There is no physical contact between the shaft adapter 110 and the motor ring 112. Consequently, there is no rubbing or drag on the shaft 42. Sealing is provided by pumping inert gas into the annular gap formed between the shaft adapter 110 and the motor ring 112.

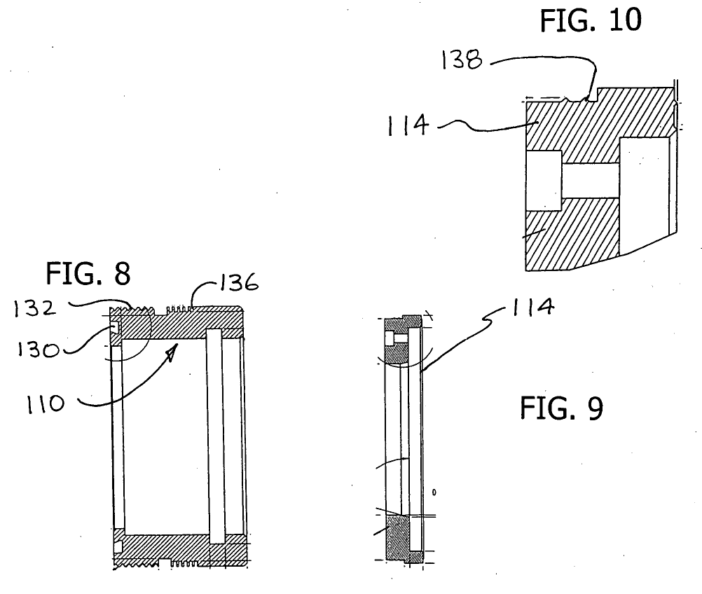

Referring now to FIG. 8, the shaft adapter 110 has a front end o-ring slot 130 for holding the o-ring 120. Spaced apart parallel grooves 136 run entirely around the outer circumference of the shaft adapter 110. Referring to FIGS. 9 and 10, the retainer ring 114 has ridges 138 for attaching to the seal ring 116. As shown in FIGS. 11, 12, 13, and 14, the motor ring 112 has a back gas inlet 140, a front gas inlet 142 and a gas outlet 144. Shaft inlets 150 extend radially inwardly at a forward inclination angle, through a tubular sleeve section 154 of the motor ring, as shown in FIG. 12. The shaft inlets 150 are advantageously equally spaced apart. A center or v-groove 152 on the inside of the sleeve section 154 intersects each of the shaft inlets 150.

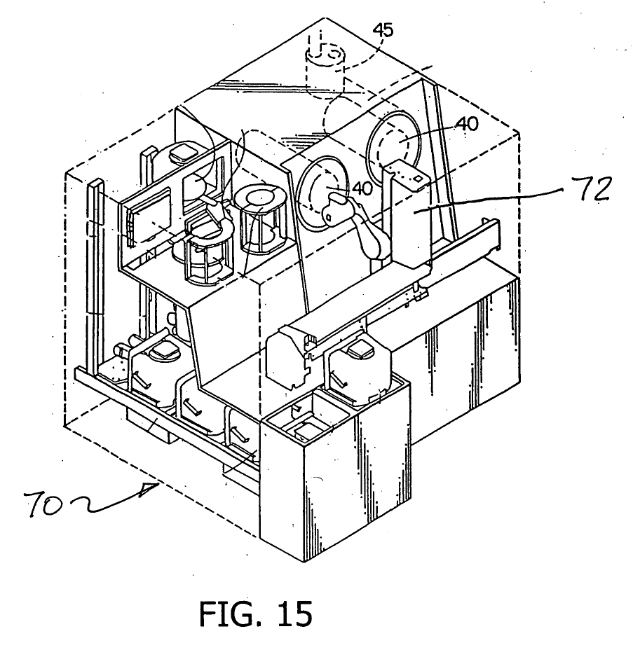

In use, workpieces 55 are loaded into the rotor 40. In the manually loaded system shown in FIGS. 1 and 2, loading is generally done by hand. In the automated system 70 shown in FIG. 15, loading is performed automatically via a robot 72, with or without use of carriers or cassettes. The door 64 is then closed, sealing off the front end 24 of the process chamber 22. A processing sequence can be preprogrammed into the system controller 18 or can be set up or selected by the operator using the control panel and display. In a typical application, ozone gas is provided into the processing chamber 22 via manifolds 60 while the motor 44 spins the rotor 40, as described in U.S. Pat. No. 6,582,525, incorporated herein by reference. The ozone gas may be sprayed into the chamber 22 as a dry gas, or it may be entrained or dissolved in a liquid.

The system 10 can of course be used to perform various process steps, using various other liquids and gasses. In one ozone process, heated DI water (provided by a heater 43 in the system or separately supplied) is sprayed into the processing chamber 22. The DI water is preferably heated to a temperature of 30 to 110° C., more preferably 40 or 50 or 60-90° C. The heated water forms a thin layer on the spinning wafers. The ozone diffuses through the heated boundary layer and/or moves via bulk transport to react at the surface of the workpiece, as described in U.S. Pat. No. 6,267,125, and U.S. Pat. No. 6,497,768, incorporated by reference.

As shown in FIG. 7, the front end of the seal 100 projects through the opening 105 in the back wall 107 of the chamber 22. A bowl seal 108 between the seal 100 and the back wall 107 prevents flow of any liquid or gases rearwardly through the opening 105. Process gases introduced into the chamber 22, such as ozone, can move radially inwardly in the gap G, towards the gap AG in the seal 100. The seal 100 prevents the process gases from passing out of the chamber 22 through the gap AG, via gas flow, and without physical contact between the shaft adapter 110 and the sleeve section 154. A suitable inert gas, such as nitrogen, clean dry air, etc. (referred to here simply as nitrogen), is provided to the inlet 142 from a pressurized source 164. The nitrogen flows through the motor ring 112 as shown in the arrows in FIG. 7.

After the nitrogen passes through the shaft inlets 150 and comes to the center or v-groove 152, the flow of nitrogen splits. A first stream of nitrogen flows rearwardly over and around the grooves 136. A second stream of nitrogen flows forwardly in the annular gap between the shaft adapter 110 and the motor ring 112, over the ridges or threads 132. Since the gas pressure of the nitrogen is maintained higher than the pressure of the process gas in the chamber 22, the second stream of nitrogen flows forwardly through the gap AG, and into the process, chamber. This forward flow of nitrogen prevents process gases from passing through the seal 100, as they cannot flow or travel upstream against the nitrogen gas flowing in the opposite direction. Consequently, the process gasses and/or liquids are sealed within the chamber.

The second or rearward flow of nitrogen moves rearwardly out of the seal and into the collection space 160 behind the shaft adapter 110. Nitrogen in the collection space 160 then flows out to a system vent through the outlet 144. An aspirator or vacuum source 162 may be used to assist the flow of nitrogen through the seal, and to help to control or limit ingress of nitrogen into the chamber. The flow of nitrogen, as described above, seals the process gases within the process chamber 22. Process liquids, and vapors of process liquids, are similarly sealed within the chamber 22.

During certain processing steps, it is advantageous to have a high concentration of ozone gas in the chamber 22. Ozone gas in the chamber 22 can be diluted by the nitrogen gas used in the seal 100. Specifically, the nitrogen flowing through the seal 100 and into the chamber 22 can dilute the ozone gas in the chamber, especially near the back of the chamber, adjacent to the seal 100 where the nitrogen enters. To reduce or avoid dilution of the ozone (or other process gas or vapor in the chamber 22), the flow rate of nitrogen through the seal 100 can be temporarily reduced.

Typical flow rates of nitrogen into the seal 100 range from 10-30 liters/minute. These flow rates will of course vary depending on the specific seal design. By temporarily reducing this gas flow rate, at the times when a high ozone concentration is desired in the chamber 22, dilution can be largely avoided. The reduced flow rate is selected based on balancing the amount of dilution acceptable against the amount of reduction in sealing effectiveness of the seal 100 running at a reduced nitrogen flow. At full nitrogen flow of e.g., 15-25 liters/minute, there is significant potential for dilution of the process gas in the chamber 22. However, the potential for leakage of process gas past the seal is negligible at these flow rates of nitrogen. At the other extreme, if the flow rate of nitrogen to the seal 100 is stopped completely, there is no potential for dilution of the process gas in the chamber 22. However, the potential for leakage of process gas past the seal in significantly greater.

Preferably, to reduce dilution of the ozone or process gas in the chamber 22, the flow rate of nitrogen to the seal is reduced to from %5 to %20, %30, %40 or %50 of the normal flow used when dilution of process gas is not a concern. Typically, the flow will be reduced to %5-%20 or about %8-%12 of normal, although these percentages will vary with different seal designs. Of course, any reduction at all from the normal flow of nitrogen can be helpful in reducing dilution of the process gas. The corresponding loss in the effectiveness of the seal 100 resulting from reducing the nitrogen flow through the seal 100 is acceptable since it is only temporary and occurs only over short intervals of time. Consequently, the cumulative amount of process gas leakage past the seal 100 resulting from reducing the flow of nitrogen, is low. In addition, any process gas leaking out of the chamber 22 necessarily flows in the annular gap between the shaft adapter 110 and the motor ring 112, and into the collection space 160. Gas in the collection space 160 is evacuated via the gas outlet 144, and from there may optionally be routed to the ozone destructor. 45 or other exhaust gas handling equipment. Accordingly, no process gas is released out of the system 10.

After the cleaning and/or stripping steps are performed, the workpieces 55 are typically rinsed using DI water that is sprayed from the manifolds 60, and then dried with a drying gas, such as N₂ gas. A purge gas, such as N₂ gas, may be used between the rinsing and drying steps, or between other processing steps, to remove excess fluids from the processing chamber. Exhaust vapors and gases flow out of the chamber through the exhaust port 62 and into the ozone destructor 45. Ozone in the ozone destructor is converted in oxygen gas which flows out of the system enclosure via an exhaust gas duct 63, along with other exhaust gases or vapors, such as exhaust from the vent 62. The various processing steps may be repeated one or more times to enhance the cleaning or stripping processes, as desired.

The processing system 10 and methods described herein may be used in several different workpiece-processing applications, such as the following: (1) post-ash cleaning; (2) photoresist stripping; (3) organic material cleaning (4) photo reworking/reclaiming; (5) post-etch cleaning; and any other suitable processing applications.

While embodiments and applications of the present invention have been shown and described, it will be apparent to one skilled in the art that other modifications are possible without departing from the inventive concepts herein. The invention, therefore, is not to be restricted except by the following claims and their equivalents.

1. An apparatus for processing a workpiece, comprising:
a process chamber;
a rotor for holding workpieces within the process chamber;
a shaft attached to and supporting the rotor for rotation within the process chamber;
a seal around the shaft, with the seal including:
a shaft adapter on the shaft;
a shaft seal element providing a seal between the shaft and the shaft adapter;
a front seal element providing a seal between the shaft adapter and the rotor;
a motor ring around the shaft adapter and spaced apart from the shaft adapter to form an annular gas flow path between them.

2. The apparatus of claim 1 further comprising a retainer ring attached to the motor ring and sealed against the motor ring by a motor ring seal element.

3. The apparatus of claim 1 further comprising a seal ring attached to the retainer ring, with the seal ring projecting into a groove on a back surface of the rotor.

4. The apparatus of claim 1 wherein the shaft seal element and the front seal element comprise an o-ring.

5. The apparatus of claim 1 further comprising a gas inlet and a gas outlet in the motor ring providing a gas flow passageway through the motor ring to ring grooves on an outer surface of the shaft adapter.

6. The apparatus of claim 5 further comprising a gas source connected to the gas inlet, and a gas vent connected to the gas outlet, for providing a flow of gas through the seal during workpiece processing, to prevent process gases introduced into the processing chamber from leaking out along the shaft, and to prevent contaminants from leaking into the process chamber along the shaft.

7. The apparatus of claim 1 further comprising a bearing supporting the shaft, and with the seal positioned between the bearing and the rotor.

8. The apparatus of claim 5 further comprising a plurality of ridges on the shaft adapter spaced apart from the ring grooves by a center groove, with the motor ring surrounding the ridges and ring grooves, and with the gas inlets leading into the center groove.

9. The apparatus of claim 1 wherein the motor ring is spaced apart from the shaft adapter by a gap of 0.005-0.020 inches.

10. The apparatus of claim 1 wherein the motor ring is spaced apart from the shaft adapter by a gap of 0.008-0.012 inches.

11. The apparatus of claim 6 further comprising a gas source flow controller between the gas source and the gas inlet, for controlling flow of gas into the seal during workpiece processing.

12. The apparatus of claim 11 further comprising an ozone gas source connected to supply ozone gas into the process chamber, and with the gas source flow controller reducing flow of gas into the seal when ozone is provided into the process chamber, to avoid diluting the ozone gas in the chamber.

13. The apparatus of claim 12 wherein the gas source comprises a nitrogen gas source, and wherein the flow of nitrogen gas into the seal is reduced from 10-30 liters per minute to less than 5 liters per minute, when ozone gas is provided into the process chamber.

14. An apparatus for processing a workpiece, comprising:
a process chamber;
an ozone gas source connected to supply ozone gas into the process chamber;
a rotor for holding workpieces within the process chamber;
a shaft attached to and supporting the rotor for rotation within the process chamber;
a gas pressure seal around the shaft;
a gas source connected to supply gas to the gas pressure seal; and
a gas flow controller for reducing flow of gas to the gas pressure seal, at times when ozone gas is provided into the process chamber.

15. The apparatus of claim 14 with the seal further comprising:
a shaft adapter on the shaft;
a shaft o-ring providing a seal between the shaft and the shaft adapter;
a front o-ring providing a seal between the shaft adapter and the rotor; and
a motor ring around the shaft adapter and spaced apart from the shaft adapter to form an annular gas flow path between them.

16. The apparatus of claim 15 further comprising a retainer ring attached to the motor ring and sealed against the motor ring by a motor ring seal element.

17. The apparatus of claim 15 further comprising a seal ring attached to the retainer ring, with the seal ring projecting into a groove on a back surface of the rotor.

18. The apparatus of claim 16 wherein the motor ring is spaced apart from the shaft adapter by a gap of 0.008-0.020 inches.

19. The apparatus of claim 1 wherein the motor ring is spaced apart from the shaft adapter by a gap of 0.008-0.012 inches.

20. The apparatus of claim 15 wherein the gas source comprises a nitrogen gas source, and wherein the flow of nitrogen gas into the seal is reduced from 10-30 liters per minute to less than 5 liters per minute, when ozone gas is provided into the process chamber.
